(19) United States
(12) Patent Application Publication
(10) Pub. No.: US 2024/0268158 A1
(43) Pub. Date: Aug. 8, 2024

(54) DISPLAY SUBSTRATE AND METHOD FOR MANUFACTURING SAME, AND DISPLAY DEVICE

(71) Applicants: CHENGDU BOE OPTOELECTRONICS TECHNOLOGY CO., LTD., Chengdu (CN); BOE TECHNOLOGY GROUP CO., LTD., Beijing (CN)

(72) Inventors: Chengjie QIN, Beijing (CN); Wei ZHANG, Beijing (CN); Benlian WANG, Beijing (CN); Yue LONG, Beijing (CN); Weiyun HUANG, Beijing (CN); Yanxia XIN, Beijing (CN); Wei HE, Beijing (CN); Xueping LI, Beijing (CN); Xiaofei YANG, Beijing (CN); Xiaoliang GUO, Beijing (CN)

(21) Appl. No.: 18/559,176

(22) PCT Filed: Oct. 10, 2022
(86) PCT No.: PCT/CN2022/124368

§ 371 Date: Nov. 6, 2023

(30) Foreign Application Priority Data
Nov. 30, 2021 (CN) 202111448253.1

(51) Int. Cl. H10K 59/122; H10K 50/16; H10K 50/19; H10K 59/12; H10K 59/121

(52) U.S. Cl. CPC H10K 59/122; H10K 50/16; H10K 50/19; H10K 59/1201; H10K 59/1216

(57) ABSTRACT

Provided are a display substrate, a manufacturing method thereof and a display device. In the display substrate, the second separation part has a protruding part, the protruding part protrudes relative to a side of the first separation part close to the second separation part, at least one sub-functional layer of the light-emitting functional layer is disconnected at the protruding part, a material of the first separation part includes an organic material, a material of the second separation part includes an organic material, and along a direction from the first electrode to the second electrode, an orthographic projection of the separation structure on the base substrate gradually decreases and then gradually increases.

### CROSS-REFERENCE TO RELATED APPLICATION

For all purposes, the present application claims the priority of the Chinese patent application No. 202111448253.1 filed on Nov. 30, 2021, the entire disclosure of which is incorporated herein by reference as part of the present application.

### TECHNICAL FIELD

Embodiments of the present disclosure relate to a display substrate, a manufacturing method thereof and a display device.

### BACKGROUND

With the continuous development of display technology, organic light-emitting diode (OLED) display devices have become a research hotspot and technology development direction for major manufacturers owing to their advantages such as wide color gamut, high contrast, thin and light design, self-illumination, and wide viewing angle.

At present, organic light-emitting diode display devices have been widely used in various electronic products, ranging from small electronic products such as smart bracelets, smart watches, smart phones, and tablet computers to large electronic products such as laptops, desktops, and televisions. Therefore, the market demand for active matrix organic light-emitting diode display devices is also increasing.

### SUMMARY

Embodiments of the present disclosure provide a display substrate, a manufacturing method thereof and a display device.

Embodiments of the present disclosure provide a display substrate, including: a base substrate; a plurality of sub-pixels located on a main surface of the base substrate, the sub-pixel including a light-emitting element, the light-emitting element having a light-emitting region, the light-emitting element including a first electrode, a light-emitting functional layer, and a second electrode, the second electrode being located on a side of the light-emitting functional layer facing away from the base substrate, the first electrode being located on a side of the light-emitting functional layer close to the base substrate, and the light-emitting functional layer including a plurality of sub-functional layers; and a separation structure located between light-emitting regions of adjacent sub-pixels and including a first separation part and a second separation part which are stacked; the first separation part is located on a side of the second separation part close to the base substrate, the second separation part has a protruding part, the protruding part protrudes relative to a side of the first separation part close to the second separation part, at least one sub-functional layer of the light-emitting functional layer is disconnected at the protruding part, a material of the first separation part includes an organic material, a material of the second separation part includes an organic material, and along a direction from the first electrode to the second electrode, an orthographic projection of the separation structure on the base substrate gradually decreases and then gradually increases.

According to the display substrate provided by embodiments of the present disclosure, the second separation part is in contact with the first separation part.

According to the display substrate provided by embodiments of the present disclosure, the separation structure is in the shape of a gourd or an hourglass.

According to the display substrate provided by embodiments of the present disclosure, the separation structure includes a bottom surface, a top surface, and two side surfaces located between the bottom surface and the top surface, the side surfaces are V-shaped, and the bottoms of the two V characters are arranged opposite to each other.

According to the display substrate provided by embodiments of the present disclosure, on the same side of the separation structure, an included angle between a side surface of the first separation part and a side surface of the second separation part is greater than or equal to 60 degrees and less than or equal to 150 degrees.

According to the display substrate provided by embodiments of the present disclosure, an included angle between a portion of the second separation part close to the top surface of the separation structure and the top surface is an acute angle, and the acute angle is greater than or equal to 60 degrees and less than or equal to 80 degrees.

According to the display substrate provided by embodiments of the present disclosure, an included angle between a portion of the second separation part close to a top surface of the separation structure and the top surface is an obtuse angle, and the obtuse angle is greater than 110 degrees and less than or equal to 160 degrees.

According to the display substrate provided by embodiments of the present disclosure, the display substrate further includes: a pixel-defining pattern including a plurality of openings, each of the plurality of openings being configured to define the light-emitting region of the sub-pixel and configured to expose at least a portion of the first electrode, the pixel-defining pattern includes a portion located in the same layer as the first separation part.

According to the display substrate provided by embodiments of the present disclosure, the pixel-defining pattern is at least partially separated from the first separation part, and both the pixel-defining pattern and the first separation part are in contact with the same insulating layer and located on the insulating layer.

According to the display substrate provided by embodiments of the present disclosure, the pixel-defining pattern includes a first pixel-defining part and a second pixel-defining part between two adjacent openings, the separation structure is located between the first pixel-defining part and the second pixel-defining part, a first recess is provided between the separation structure and the first pixel-defining part, and a second recess is provided between the separation structure and the second pixel-defining part.

According to the display substrate provided by embodiments of the present disclosure, an orthographic projection of the protruding part on the base substrate at least partially overlaps an orthographic projection of the first electrode on the base substrate.

According to the display substrate provided by embodiments of the present disclosure, the pixel-defining pattern and the separation structure are of an integral structure.

According to the display substrate provided by embodiments of the present disclosure, a material of the first separation part includes a positive photoresist, and a material of the second separation structure includes a negative photoresist.

According to the display substrate provided by embodiments of the present disclosure, the light-emitting functional layer includes a charge generation layer, a first light-emitting layer, and a second light-emitting layer which are stacked, the first light-emitting layer is located between the first electrode and the charge generation layer, the second light-emitting layer is located between the second electrode and the charge generation layer, and the charge generation layer is disconnected at the protruding part.

According to the display substrate provided by embodiments of the present disclosure, the light-emitting functional layer further includes a first charge transport layer located between the first electrode and the first light-emitting layer and a second charge transport layer located between the first light-emitting layer and the charge generation layer, and the first charge transport layer and the second charge transport layer are disconnected at the protruding part.

According to the display substrate provided by embodiments of the present disclosure, the separation structure includes at least one separation substructure, and an orthographic projection of the at least one separation substructure on the base substrate at least surrounds one half of an orthographic projection of the light-emitting region on the base substrate.

According to the display substrate provided by embodiments of the present disclosure, the separation structure is ring-shaped so as to surround the light-emitting region, and the second electrode is continuous at the protruding part.

According to the display substrate provided by embodiments of the present disclosure, the display substrate further includes a pixel circuit, the pixel circuit is configured to drive the light-emitting element to emit light, the display substrate further includes a planarization layer, the first electrode is connected to the pixel circuit through a via hole running through the planarization layer, and both the first electrode and the first separation part are located on the planarization layer.

According to the display substrate provided by embodiments of the present disclosure, both the first electrode and the first separation part are in contact with the planarization layer.

According to the display substrate provided by embodiments of the present disclosure, the pixel circuit includes a capacitor, and an orthographic projection of the capacitor on the base substrate at least partially overlaps an orthographic projection of the separation structure on the base substrate.

According to the display substrate provided by embodiments of the present disclosure, the display substrate further includes a conductive structure, the conductive structure is configured to provide a signal to the pixel circuit, the conductive structure is located between the separation structure and the base substrate, and an orthographic projection of the conductive structure on the base substrate overlaps the orthographic projection of the separation structure on the base substrate.

According to the display substrate provided by embodiments of the present disclosure, the conductive structure is located between light-emitting regions of adjacent sub-pixels, and the conductive structure is electrically connected to the second electrode.

According to the display substrate provided by embodiments of the present disclosure, the minimum dimension of the separation structure in a plane parallel to the main surface is greater than a spacing between the first electrodes of adjacent sub-pixels.

According to the display substrate provided by embodiments of the present disclosure, the maximum dimension of the separation structure in a plane parallel to the main surface is greater than or equal to one fifth of a spacing between the first electrodes of adjacent sub-pixels.

Embodiments of the present disclosure further provide a display device, including any one of the display substrates as described above.

Embodiments of the present disclosure further provide a manufacturing method of a display substrate, including: forming a plurality of sub-pixels on a main surface of a base substrate, the sub-pixel including a light-emitting element, the light-emitting element having a light-emitting region, the light-emitting element including a first electrode, a light-emitting functional layer, and a second electrode, the second electrode being located on a side of the light-emitting functional layer facing away from the base substrate, the first electrode being located on a side of the light-emitting functional layer close to the base substrate, and the light-emitting functional layer including a plurality of sub-functional layers; and forming a separation structure between light-emitting regions of adjacent sub-pixels; forming the separation structure includes forming a first separation part and a second separation part which are stacked, and the first separation part is located on a side of the second separation part close to the base substrate, the second separation part has a protruding part, the protruding part protrudes relative to a side of the first separation part close to the second separation part, at least one sub-functional layer of the light-emitting functional layer is disconnected at the protruding part, a material of the first separation part includes an organic material, a material of the second separation part includes an organic material, and along a direction from the first electrode to the second electrode, an orthographic projection of the separation structure on the base substrate gradually decreases and then gradually increases.

According to the manufacturing method of the display substrate provided by embodiments of the present disclosure, forming the first separation part and the second separation part which are stacked includes: forming a positive photoresist film; forming a negative photoresist film on the positive photoresist film; patterning the negative photoresist film to form the second separation part; and patterning the positive photoresist film by using the second separation part as a mask to form the first separation part.

### BRIEF DESCRIPTION OF THE DRAWINGS

In order to clearly illustrate the technical solution of the embodiments of the present disclosure, the drawings of the embodiments will be briefly described in the following. It is obvious that the described drawings are only related to some embodiments of the present disclosure and thus are not construed as any limitation to the present disclosure.

FIG. 1 is a schematic diagram of a light-emitting element.

FIG. 2 is a schematic diagram of a display substrate.

FIG. 3 is a cross-sectional view of a display substrate provided by an embodiment of the present disclosure.

FIG. 4 is an enlarged view of the separation structure in FIG. 3.

FIG. 5 is a cross-sectional view of another display substrate provided by an embodiment of the present disclosure.

FIG. 6 is an enlarged view of the separation structure in FIG. 5.

FIG. 7 is a cross-sectional view of another display substrate provided by an embodiment of the present disclosure.

FIG. 8 is an enlarged view of the separation structure in FIG. 7.

FIG. 9A is a schematic diagram of a separation structure of a display substrate provided by an embodiment of the present disclosure.

FIG. 9B is a schematic diagram of a separation structure of a display substrate provided by an embodiment of the present disclosure.

FIG. 10 is a schematic diagram of light-emitting elements in a display substrate provided by an embodiment of the present disclosure.

FIG. 11 is a schematic plan view of another display substrate provided by an embodiment of the present disclosure.

FIG. 12 is a schematic plan view of another display substrate provided by an embodiment of the present disclosure.

FIG. 13 is a schematic diagram of a pixel circuit and a light-emitting element in a display substrate.

FIG. 14A is a schematic diagram of a display substrate provided by an embodiment of the present disclosure.

FIG. 14B is a schematic diagram of a display substrate provided by another embodiment of the present disclosure.

FIG. 15 is a schematic diagram of a display device provided by an embodiment of the present disclosure.

FIG. 16A to FIG. 16D are schematic diagrams of a manufacturing method of a display substrate provided by an embodiment of the present disclosure.

FIG. 17A is a schematic cross-sectional view of a negative photoresist after exposure and development.

FIG. 17B is a schematic cross-sectional view of a positive photoresist after exposure and development.

FIG. 18A to FIG. 18C are schematic diagrams of a manufacturing method of a display substrate provided by an embodiment of the present disclosure.

### DETAILED DESCRIPTION

For more clear understanding of the objectives, technical details and advantages of the embodiments of the present disclosure, the technical solutions of the embodiments will be described in a clearly and fully understandable way in connection with the drawings related to the embodiments of the present disclosure. It is obvious that the described embodiments are just a part but not all of the embodiments of the present disclosure. Based on the described embodiments herein, those skilled in the art can obtain other embodiment(s), without any inventive work, which should be within the scope of the present disclosure.

Unless otherwise defined, all the technical and scientific terms used herein have the same meanings as commonly understood by one of ordinary skill in the art to which the present disclosure belongs. The terms “first,” “second,” etc., which are used in the present disclosure, are not intended to indicate any sequence, amount or importance, but distinguish various components. Also, the terms “comprise”, “comprising”, “include”, “including”, etc., are intended to specify that the elements or the objects stated before these terms encompass the elements or the objects and equivalents thereof listed after these terms, but do not preclude the other elements or objects. The phrases “connect”, “connected” and the like are not limited to a physical or mechanical connection, but also include an electrical connection, either directly or indirectly. The phrases “on,” “under,” “right,” “left” and the like are only used to indicate relative position relationship, and when the position of the described object is changed, the relative position relationship may be changed accordingly.

With the continuous development of display technology, people's pursuit of display quality is getting higher and higher. In order to further reduce power consumption and achieve high brightness, one light-emitting layer in the light-emitting element in an OLED display panel can be replaced by two light-emitting layers, a charge generation layer (CGL) is added between the two light-emitting layers, and N/P-CGL is used as a heterojunction to connect two light-emitting component structures in series to form a double-stack design, thereby forming a tandem structure. The display substrate with the tandem structure realizes series connection of double light-emitting components, thus greatly reducing the luminous current of the light-emitting element under the same luminous intensity, increasing the lifespan of the light-emitting element, and facilitating the development and mass production of new technologies such as vehicles with a long lifespan. A display device with a tandem structure has the advantages of a long lifespan, low power consumption, and high brightness.

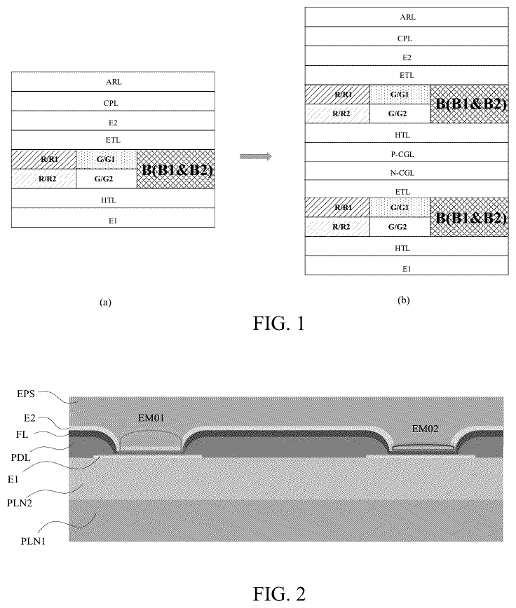

FIG. 1 is a schematic diagram of a light-emitting element. FIG. 1(a) is a schematic diagram of a traditional light-emitting element. FIG. 1(b) is a schematic diagram of a light-emitting element with a tandem structure. As illustrated in FIG. 1(b), the charge generation layers (CGL) between different light-emitting elements of the tandem structure are connected.

FIG. 1 illustrates a first electrode E1, a second electrode E2, a hole transport layer HTL, an electron transport layer ETL, a light coupling layer CPL, an anti-reflection layer ARL, a P-type doped charge generation layer P-CGL, an N-type doped charge generation layer N-CGL, a light-emitting layer R, a light-emitting layer G, and a light-emitting layer B. The light-emitting layer R includes two sublayers including a light-emitting material R1 and a light-emitting material R2 respectively, the light-emitting layer G includes two sublayers including a light-emitting material G1 and a light-emitting material G2 respectively, and the light-emitting layer B includes a light-emitting material B1 and a light-emitting material B2. The light-emitting material R1 and the light-emitting material R2 are two different materials that emit red light, the light-emitting material G1 and the light-emitting material G2 are two different materials that emit green light, and the light-emitting material B1 and the light-emitting material B2 are two different materials that emit blue light.

FIG. 2 is a schematic diagram of a display substrate. As illustrated in FIG. 2, the display substrate includes a planarization layer PLN1, a planarization layer PLN2, a pixel-defining layer PDL, an electrode E1, a light-emitting functional layer FL, an electrode E2, and an encapsulation layer EPS. FIG. 2 illustrates the light-emitting element EM01 and the light-emitting element EM02, the charge generation layers (CGL) of the light-emitting element EM01 and the light-emitting element EM02 can be integrated and can be fabricated by using an open mask.

However, the inventor(s) noticed that for high-resolution products, because the charge generation layer has strong conductivity and the light-emitting functional layers (the light-emitting functional layer herein refers to a film layer including two light-emitting layers and a charge generation layer) of adjacent sub-pixels are connected, the charge generation layer is likely to cause crosstalk between adjacent sub-pixels, thereby affecting the product quality and seriously affecting the display quality.

For example, the crosstalk between adjacent sub-pixels refers to a situation where a light-emitting element that should not emit light emits light. As illustrated in FIG. 2, if the desired situation is that the light-emitting element EM01 emits light and the light-emitting element EM02 does not emit light, but due to the conductivity of the charge generation layer, the light-emitting element EM02 also emits light, thus leading to crosstalk.

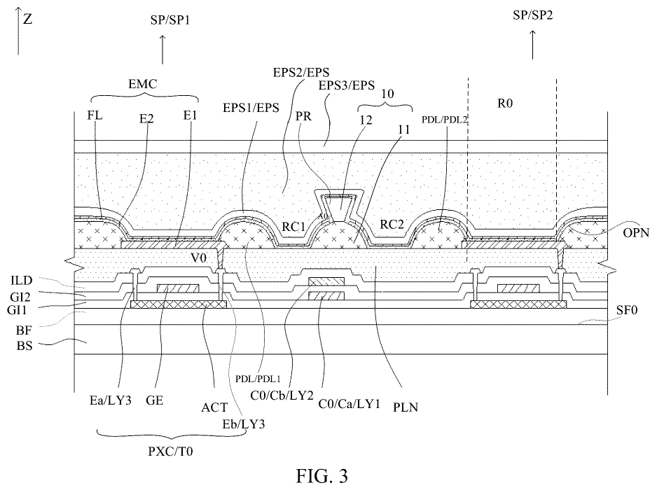

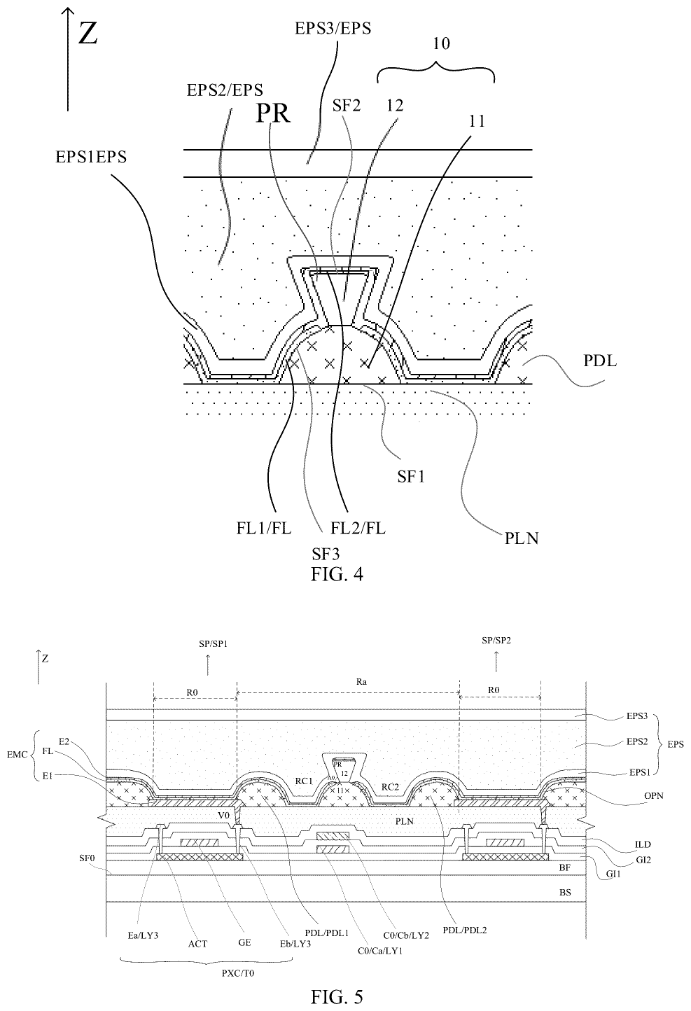

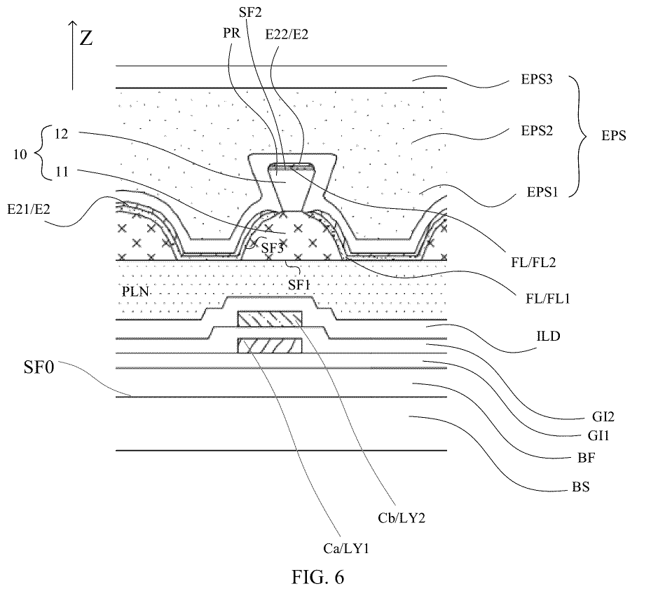

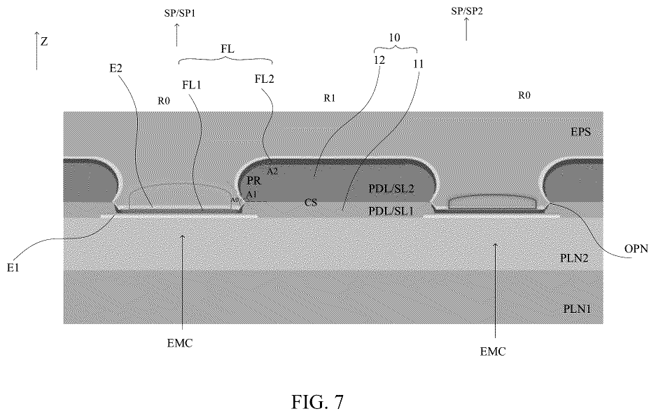

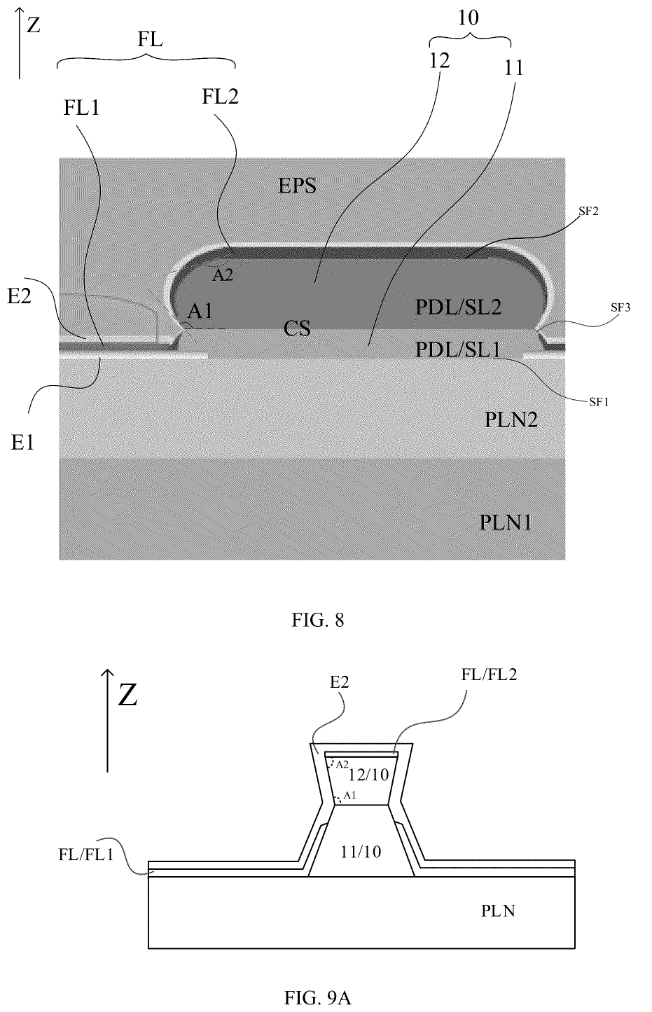

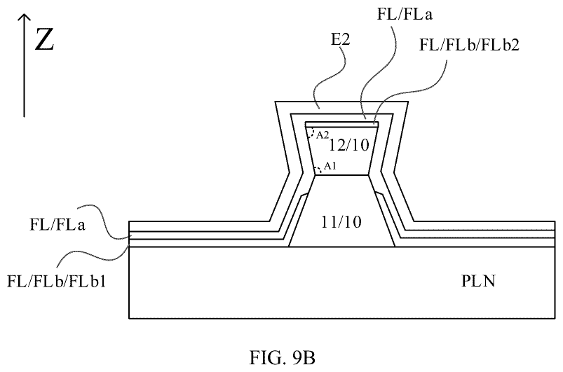

FIG. 3 is a cross-sectional view of a display substrate provided by an embodiment of the present disclosure. FIG. 4 is an enlarged view of the separation structure in FIG. 3. FIG. 5 is a cross-sectional view of another display substrate provided by an embodiment of the present disclosure. FIG. 6 is an enlarged view of the separation structure in FIG. 5. FIG. 7 is a cross-sectional view of another display substrate provided by an embodiment of the present disclosure. FIG. 8 is an enlarged view of the separation structure in FIG. 7. FIG. 9A is a schematic diagram of a separation structure of a display substrate provided by an embodiment of the present disclosure. FIG. 9B is a schematic diagram of a separation structure of a display substrate provided by an embodiment of the present disclosure.

As illustrated in FIG. 3, FIG. 5 and FIG. 7, embodiments of the present disclosure provide a display substrate, including: a base substrate BS, a plurality of sub-pixels SP, and a separation structure 10.

As illustrated in FIG. 3 and FIG. 5, the plurality of sub-pixels SP are located on the main surface SF0 of the base substrate BS, the sub-pixel SP includes a light-emitting element EMC, and the light-emitting element EMC has a light-emitting region R0. FIG. 7 also illustrates the light-emitting element EMC and the light-emitting region R0.

As illustrated in FIG. 3, FIG. 5 and FIG. 7, the light-emitting element EMC includes a first electrode E1, a light-emitting functional layer FL, and a second electrode E2, the second electrode E2 is located on the side of the light-emitting functional layer FL facing away from the base substrate BS, the first electrode E1 is located on the side of the light-emitting functional layer FL close to the base substrate BS, and the light-emitting functional layer FL includes a plurality of sub-functional layers.

For example, the first electrode E1 is made of a conductive material. For example, the material of the first electrode E1 includes a metal and a conductive metal oxide. For example, the first electrode E1 adopts a stacked structure of indium tin oxide (ITO), silver (Ag), and indium tin oxide (ITO). The material and structure of the first electrode E1 can be set as required.

For example, the second electrode E2 is made of a conductive material. For example, the material of the second electrode E2 includes a metal or alloy. For example, the material of the second electrode E2 includes Mg/Ag alloy. The material and structure of the second electrode E2 can be set as required.

For example, the second electrodes E2 of different sub-pixels are electrically connected so as to provide the same voltage signal.

As illustrated in FIG. 3, FIG. 5 and FIG. 7, the separation structure 10 is located between the light-emitting regions R0 of adjacent sub-pixels SP, and includes a first separation part 11 and a second separation part 12 which are stacked. The first separation part 11 is located on the side of the second separation part 12 close to the base substrate BS; the second separation part 12 has a protruding part PR, and the protruding part PR protrudes from the first separation part 11, for example, the protruding part PR protrudes relative to the side of the first separation part 11 close to the second separation part 12; at least one sub-functional layer of the light-emitting functional layer FL is disconnected at the protruding part PR, and along the direction from the first electrode E1 to the second electrode E2, the orthographic projection of the separation structure 10 on the base substrate BS gradually decreases and then gradually increases. For example, the direction from the first electrode E1 to the second electrode E2 is the direction Z. The structure that narrows first and then widens of the separation structure 10 helps to disconnect at least one sub-functional layer of the light-emitting functional layer FL.

For example, as illustrated in FIG. 3, FIG. 5 and FIG. 7, the protruding part PR protrudes relative to the top surface of the first separation part 11.

For example, disconnection of one element at the protruding part PR includes disconnection at the side surface of the protruding part PR.

For example, the material of the first separation part 11 includes an organic material, and the material of the second separation part 12 includes an organic material. For example, the organic material includes a resin, but is not limited thereto. For example, the organic material includes one of acrylic, polyethylene terephthalate, polyimide, polyamide, polycarbonate, epoxy resin, and the like, or a combination thereof. For example, the material of the first separation part 11 may include a photoresist, and the material of the second separation part 12 may include a photoresist.

For example, the material of the second separation part 12 is different from that of the first separation part 11.

For example, as illustrated in FIG. 3, FIG. 5 and FIG. 7, the cross-section of the second separation part 12 is an inverted trapezoid, but is not limited thereto, and the cross-section of the second separation part 12 can also be of any other suitable shapes.

As illustrated in FIG. 3, FIG. 5 and FIG. 7, the plurality of sub-pixels SP include a sub-pixel SP1 and a sub-pixel SP2. The sub-pixel SP1 and the sub-pixel SP2 are two adjacent sub-pixels. The number of sub-pixels disposed on the display substrate is not limited to what is illustrated in the figures, and can be set as required.

In the embodiments of the present disclosure, the number of sub-functional layers included in the light-emitting functional layer FL can be set as required.

In the display substrate provided by the embodiments of the present disclosure, a separation structure can be provided between adjacent sub-pixels, and at least one of the pluarality of sub-functional layers in the light-emitting functional layer is disconnected at the position where the separation structure is located, to increase the resistance of the sub-functional layer with high conductivity in the light-emitting functional layer FL, thereby reducing the crosstalk between adjacent sub-pixels caused by the film layer with high conductivity in the plurality of sub-functional layers.

In the display substrate provided by the embodiments of the present disclosure, the separation structure 10 is formed after the first electrode E1 is formed, without changing the backplane structure of the display substrate, and there is no risk such as the presence of adhesive-coating halos. In addition, the separation structure 10 is disposed between the first electrodes E1 of the light-emitting element, so that there is a large space to arrange the separation structure 10, thus facilitating the arrangement of separation structures 10 of different structures.

As illustrated in FIG. 3 and FIG. 5, according to the display substrate provided by the embodiments of the present disclosure, the separation structure 10 is hourglass-shaped. As illustrated in FIG. 7, the separation structure 10 is gourd-shaped or inverted gourd-shaped. In the cross-sectional view, the separation structure 10 is narrowed at the contact position between the first separation part 11 and the second separation part 12, and the dimension of one end of the separation structure close to the base substrate BS and one end away from the base substrate BS is greater than the dimension of a portion of the separation structure 10 at the narrowed position.

As illustrated in FIG. 3, FIG. 5 and FIG. 7, the separation structure 10 may be disposed between sub-pixels in the display area of the display substrate.

As illustrated in FIG. 4, FIG. 6 and FIG. 8, according to the display substrate provided by the embodiments of the present disclosure, the separation structure 10 includes a bottom surface SF1, a top surface SF2, and two side surfaces SF3 between the bottom surface SF1 and the top surface SF2. The SF3 is V-shaped, and the bottoms of the two V characters are arranged opposite to each other.

As illustrated in FIG. 3, FIG. 5 and FIG. 7, according to the display substrate provided by the embodiments of the present disclosure, the display substrate further includes: a pixel-defining pattern PDL including a plurality of openings OPN configured to define the light-emitting region R0 of the sub-pixel SP and configured to expose at least a portion of the first electrode E1.

As illustrated in FIG. 3 to FIG. 6, the pixel-defining pattern PDL is located in the same layer as the first separation part 11. In the embodiments of the present disclosure, that two elements are located in the same layer means that the two elements are formed of the same film layer by a patterning process.

As illustrated in FIG. 3 to FIG. 6, according to the display substrate provided by the embodiments of the present disclosure, the pixel-defining pattern PDL is at least partially separated from the first separation part 11, and both the pixel-defining pattern PDL and the first separation part 11 are in contact with the same insulating layer and located on the insulating layer. FIG. 3 to FIG. 6 illustrate that both the pixel-defining pattern PDL and the first separation part 11 are in contact with the planarization layer PLN and are located on the planarization layer PLN.

As illustrated in FIG. 3 and FIG. 5, according to the display substrate provided by the embodiments of the present disclosure, the pixel-defining pattern PDL includes a first pixel-defining part PDL1 and a second pixel-defining part PDL2 that are located between two adjacent openings OPN, the separation structure 10 is located between the first pixel-defining part PDL1 and the second pixel-defining part PDL2, a first recess RC1 is provided between the separation structure 10 and the first pixel-defining part PDL1, and a second recess RC2 is provided between the separation structure 10 and the second pixel-defining part PDL2.

As illustrated in FIG. 3 and FIG. 5, the first recess RC1 and the second recess RC2 are filled with an encapsulation layer EPS.

In the embodiments of the present disclosure, as illustrated in FIG. 3 to FIG. 6, the encapsulation layer EPS includes a first encapsulation layer EPS1, a second encapsulation layer EPS2, and a third encapsulation layer EPS3. For example, the first encapsulation layer EPS1 and the third encapsulation layer EPS3 are inorganic layers, and can be formed by a chemical vapor deposition (CVD) process. The second encapsulation layer EPS2 is an organic layer, and can be formed by an inkjet printing process. As illustrated in FIG. 3 to FIG. 6, the thickness of the second encapsulation layer EPS2 is greater than that of the first encapsulation layer EPS1. As illustrated in FIG. 3 to FIG. 6, the thickness of the second encapsulation layer EPS2 is greater than that of the third encapsulation layer EPS3.

For example, the encapsulation layer EPS covers the entire display substrate and is well covered at the separation structure to prevent the light-emitting element from being corroded by water and oxygen. The separation structure 10 provided by the embodiments of the present disclosure can effectively disconnect at least one sub-functional layer in the light-emitting functional layer without affecting the thin-film encapsulation effect of the encapsulation layer. The separation structure 10 provided by the embodiments of the present disclosure does not affect the film-forming uniformity of the encapsulation layer EPS, avoids the discontinuous film-formation of the encapsulation layer, and prevents the light-emitting element from being dysfunctional due to water vapor intrusion.

As illustrated in FIG. 3 and FIG. 5, because the separation structure 10 is located between the first pixel-defining part PDL1 and the second pixel-defining part PDL2, and is spaced from the first pixel-defining part PDL1 and the second pixel-defining part PDL2 respectively, the orthographic projection of the protruding part PR on the base substrate BS does not overlap the orthographic projection of the first electrode E1 on the base substrate BS.

For example, as illustrated in FIG. 3 and FIG. 5, the included angle A2 between the portion of the second separation part 12 close to the top surface SF2 of the separation structure 10 and the top surface SF2 is an acute angle, for example, the acute angle A2 is greater than or equal to 60 degrees and less than or equal to 80 degrees.

For example, as illustrated in FIG. 3 and FIG. 5, the thickness of the second separation part 12 is greater than one half of the thickness of the first separation part 11 and less than or equal to the thickness of the first separation part 11.

For example, as illustrated in FIG. 3 and FIG. 5, the thickness of the second separation part 12 is smaller than the that of the first separation part 11.

As illustrated in FIG. 3, FIG. 5 and FIG. 7, according to the display substrate provided by the embodiments of the present disclosure, on the same side of the separation structure 10, in order to improve the encapsulation effect, the included angle A0 between the side surface of the first separation part 11 and the side surface of the second separation part 12 is greater than or equal to 60 degrees and less than or equal to 150 degrees. For example, in order to further improve the encapsulation effect, the included angle A0 between the side surface of the first separation part 11 and the side surface of the second separation part 12 is greater than 90 degrees and less than or equal to 150 degrees. Further, for example, in order to obtain a better encapsulation effect, the included angle A0 between the side surface of the first separation part 11 and the side surface of the second separation part 12 is greater than 90 degrees and less than or equal to 120 degrees. The value of the included angle A0 is related to the encapsulation effect. For example, the gentler the two sides forming the included angle A0 are, the better the encapsulation effect will be. Of course, other methods can also be used to improve the encapsulation effect.

For example, the included angle A0 is adjusted, the risk of disconnection of the second electrode E2 (e.g., cathode) is reduced, and the continuity of the inorganic layer in the encapsulation layer is improved. In addition, at the separation structure 10, auxiliary connection electrodes can also be added by using a secondary mask to connect the second electrodes E2 of different sub-pixels, or the light coupling layer CPL (as illustrated in FIG. 1) can also be made conductive. That is, the second electrodes E2 of different sub-pixels are connected through the conductive light coupling layer CPL. For example, the inorganic layer in the encapsulation layer is fabricated by chemical vapor deposition (CVD).

For example, as illustrated in FIG. 5 and FIG. 6, the included angle A2 between the portion (the side surface of the separation structure 10) of the second separation part 12 close to the top surface SF2 of the separation structure 10 and the top surface SF2 is an acute angle, for example, in order to disconnect the light-emitting functional layer, the included angle A2 is greater than or equal to 45 degrees and less than or equal to 75 degrees. For example, each of the two base angles (included angle A2) of the inverted trapezoidal second separation part 12 is greater than or equal to 45 degrees and less than or equal to 75 degrees.

As illustrated in FIG. 3 and FIG. 5, according to the display substrate provided by the embodiments of the present disclosure, the display substrate includes a capacitor C0, the capacitor C0 includes an electrode plate Ca and an electrode plate Cb, and the orthographic projection of the capacitor C0 on the base substrate BS at least partially overlaps the orthographic projection of the separation structure 10 on the base substrate BS. Of course, in other embodiments or at other positions, the orthographic projections of other structures or other wires on the base substrate BS may also at least partially overlap the orthographic projection of the separation structure 10 on the base substrate BS. These structures or wires overlapping the separation structure 10 may be located in the third conductive pattern layer LY3.

As illustrated in FIG. 3 and FIG. 5, according to the display substrate provided by the embodiments of the present disclosure, the display substrate further includes a pixel circuit PXC configured to drive the light-emitting element EMC to emit light, the display substrate further includes a planarization layer PLN, the first electrode E1 is connected to the pixel circuit PXC through a via hole V0 running through the planarization layer, and both the first electrode E1 and the first separation part 11 are located on the planarization layer PLN.

As illustrated in FIG. 7 and FIG. 8, the separation structure 10 and the pixel-defining pattern PDL are of an integral structure.

As illustrated in FIG. 7 and FIG. 8, the pixel-defining pattern PDL includes a pixel-defining sublayer SL1 and a pixel-defining sublayer SL2. The pixel-defining sublayer SL1 and the first separation part 11 are of an integral structure, and the pixel-defining sublayer SL2 and the second separation part 12 are of an integral structure. That is, the separation structure 10 also serves as a pixel-defining pattern PDL at the same time.

As illustrated in FIG. 7 and FIG. 8, according to the display substrate provided by the embodiments of the present disclosure, the orthographic projection of the protruding part PR on the base substrate BS at least partially overlaps the orthographic projection of the first electrode E1 on the base substrate BS.

As illustrated in FIG. 7 and FIG. 8, the thickness of the second separation part 12 is greater than that of the first separation part 11. For example, the thickness of the second separation part 12 is more than twice the thickness of the first separation part 11. Further, for example, the thickness of the second separation part 12 is more than three times the thickness of the first separation part 11. For example, the ratio of the thickness of the second separation part 12 to the thickness of the first separation part 11 is greater than or equal to 2 and smaller than or equal to 6.

As illustrated in FIG. 3 and FIG. 5, in the embodiments of the present disclosure, the thickness of an element refers to the dimension of the element in a direction perpendicular to the main surface SF0 of the base substrate. The direction Z is illustrated in the figures. The direction Z is the direction perpendicular to the main surface SF0 of the base substrate. As illustrated in FIG. 3 and FIG. 5, the main surface SF0 of the base substrate is a surface on which various elements are fabricated.

As illustrated in FIG. 3 to FIG. 8, according to the display substrate provided by the embodiments of the present disclosure, the second separation part 12 is in contact with the first separation part 11.

For example, as illustrated in FIG. 7 and FIG. 8, the first separation part 11 and the second separation part 12 have a contact surface CS. In order to facilitate disconnection of at least one sub-functional layer of the light-emitting functional layer and prevent disconnection of the second electrode E2 at the protruding part PR, the included angle A1 between the portion of the second separation part 12 close to the contact surface CS and the contact surface CS is an obtuse angle. For example, as illustrated in FIG. 7 and FIG. 8, the included angle A1 is greater than 90 degrees and less than or equal to 150 degrees. The included angle A1 can also be of any other values.

For example, as illustrated in FIG. 7 and FIG. 8, in order to facilitate disconnection of the light-emitting functional layer, the included angle A2 between the portion of the second separation part 12 close to the top surface SF2 of the separation structure 10 and the top surface SF2 is an obtuse angle. For example, in order to better disconnect the light-emitting functional layer, the included angle A2 is greater than 110 degrees and less than or equal to 160 degrees.

For example, as illustrated in FIG. 7 and FIG. 8, according to the display substrate provided by the embodiments of the present disclosure, the material of the first separation part 11 includes a positive photoresist, and the material of the second separation part 12 includes a negative photoresist. Thus, the separation structure 10 can be formed by utilizing the properties of the positive photoresist and the negative photoresist.

As illustrated in FIG. 3 to FIG. 8, the second electrode E2 is in contact with a portion of the side surface SF3 of the separation structure 10. As illustrated in FIG. 3 to FIG. 8, the second electrode E2 is in contact with the side surface SF3 of the separation structure 10 at the narrowed position of the separation structure 10.

As illustrated in FIG. 3 to FIG. 6, according to the display substrate provided by the embodiments of the present disclosure, both the first electrode E1 and the first separation part 11 are in contact with the planarization layer PLN.

As illustrated in FIG. 7 and FIG. 8, according to the display substrate provided by the embodiments of the present disclosure, both the first electrode E1 and the first separation part 11 are in contact with the planarization layer PLN2.

As illustrated in FIG. 3 and FIG. 5, according to the display substrate provided by the embodiments of the present disclosure, the minimum dimension of the separation structure 10 in a plane parallel to the main surface is smaller than the spacing between the first electrodes E1 of adjacent sub-pixels SP.

As illustrated in FIG. 3 and FIG. 5, according to the display substrate provided by the embodiments of the present disclosure, the maximum dimension of the separation structure 10 in a plane parallel to the main surface is greater than or equal to one fifth of the spacing between the first electrodes E1 of adjacent sub-pixels SP.

As illustrated in FIG. 7 and FIG. 8, according to the display substrate provided by the embodiments of the present disclosure, the minimum dimension of the separation structure 10 in a plane parallel to the main surface is greater than the spacing between the first electrodes E1 of adjacent sub-pixels SP.

As illustrated in FIG. 3 to FIG. 6, the display substrate includes a buffer layer BF, a gate insulating layer GI1, a gate insulating layer GI2, and an interlayer insulating layer ILD.

FIG. 3 and FIG. 5 also illustrate a thin film transistor T0, the thin film transistor T0 includes a gate electrode GE, an active layer ACT, a source electrode Ea, and a drain electrode Eb, and the first electrode E1 is connected to the drain electrode Eb. The source electrode Ea and the drain electrode Eb of the thin film transistor may be the same in structure and interchangeable in terms of names. For example, the thin film transistor TO may be a light-emitting control transistor.

FIG. 3 and FIG. 5 also illustrate the first electrode plate Ca and the second electrode plate Cb of the capacitor.

As illustrated in FIG. 3 and FIG. 5, the first conductive pattern layer LY1 includes a gate electrode GE and a first electrode plate Ca, the second conductive pattern layer LY2 includes a second electrode plate Cb, and the third conductive pattern layer LY3 includes a source electrode Ea and a drain electrode Eb.

As illustrated in FIG. 7 and FIG. 8, according to the display substrate provided by the embodiments of the present disclosure, the display substrate includes a planarization layer PLN1 and a planarization layer PLN2.

For the sake of clarity, in the drawings of the present disclosure, not all structures of the display substrate are illustrated.

FIG. 9A is a schematic diagram of a separation structure of a display substrate provided by an embodiment of the present disclosure. FIG. 9B is a schematic diagram of a separation structure of a display substrate provided by an embodiment of the present disclosure.

As illustrated in FIG. 9A, the light-emitting functional layer FL is disconnected at the protruding part of the separation structure 10 to form a light-emitting functional part FL1 and a light-emitting functional part FL2, and the light-emitting functional part FL2 is located on the separation structure 10. That is, each sub-functional layer of the light-emitting functional layer FL is disconnected at the protruding part of the separation structure 10.

As illustrated in FIG. 9A, the second electrode E2 is continuous at various positions. That is, the second electrode E2 is not disconnected by the separation structure 10. The material of the second electrode E2 is usually a metal or alloy, and the metal or alloy has good climbing performance.

The structure illustrated in FIG. 9B differs from the structure illustrated in FIG. 9A in that: some sub-functional layers of the light-emitting functional layer FL are disconnected at the protruding part of the separation structure 10, while the other sub-functional layers are not disconnected at the protruding part of the separation structure 10, thus forming a functional sub-part FLa and a functional sub-part FLb, the functional sub-part FLa is not disconnected and the functional sub-part FLb forms the disconnected parts FLb1 and FLb2.

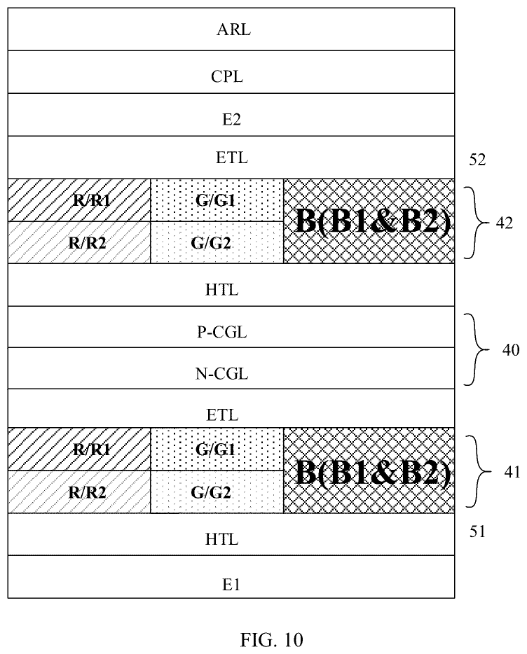

FIG. 10 is a schematic diagram of light-emitting elements in a display substrate provided by an embodiment of the present disclosure. As illustrated in FIG. 10, according to the display substrate provided by the embodiments of the present disclosure, the light-emitting functional layer FL includes a charge generation layer 40, a first light-emitting layer 41, and a second light-emitting layer 42 which are stacked, the first light-emitting layer 41 is located between the first electrode E1 and the charge generation layer 40, the second light-emitting layer 42 is located between the second electrode E2 and the charge generation layer 40, and the charge generation layer 40 is disconnected at the protruding part PR. Because the charge generation layer 40 is disconnected at the separation structure 10, the propagation path of the charge is long and the resistance of the charge generation layer in the light-emitting functional layer is large, thus effectively avoiding crosstalk between adjacent sub-pixels.

For example, in some embodiments, in addition to the disconnection of the charge generation layer 40 at the protruding part PR, the sub-functional layer between the charge generation layer 40 and the first electrode E1 is also disconnected at the protruding part PR, and the sub-functional layer between the charge generation layer 40 and the second electrode E2 is not disconnected at the protruding part PR. In other embodiments, in addition to the disconnection of the charge generation layer 40 at the protruding part PR, the sub-functional layer between the charge generation layer 40 and the first electrode E1 is also disconnected at the protruding part PR, and the sub-functional layer between the charge generation layer 40 and the second electrode E2 is also disconnected at the protruding part PR, and in this case, each sub-functional layer of the light-emitting functional layer FL is disconnected at the protruding part PR.

As illustrated in FIG. 10, according to the display substrate provided by the embodiments of the present disclosure, the light-emitting functional layer FL further includes a first charge transport layer 51 located between the first electrode E1 and the first light-emitting layer 41, a second charge transport layer 52 located between the first light-emitting layer 41 and the charge generation layer 40, and the first charge transport layer 51 and the second charge transport layer 52 are disconnected at the protruding part PR.

As illustrated in FIG. 10, the first charge transport layer 51 is a hole transport layer HTL, and the second charge transport layer 52 is an electron transport layer ETL. For other structures, reference may be made to the describing of FIG. 1.

FIG. 11 is a schematic plan view of another display substrate provided by an embodiment of the present disclosure. According to the display substrate provided by the embodiments of the present disclosure, as illustrated in FIG. 11, the separation structure 10 is ring-shaped so as to surround the light-emitting region R0, and the second electrode E2 is continuous at the protruding part of the separation structure 10 so as to facilitate signal transmission of different sub-pixels on the second electrode E2. The cross-sectional view of the separation structure 10 is as illustrated above.

As illustrated in FIG. 11, the light-emitting region R0 of each sub-pixel SP is surrounded by a separation structure 10.

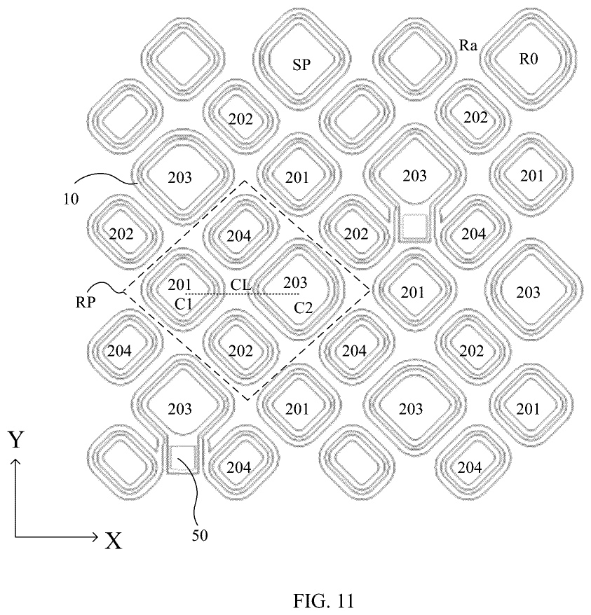

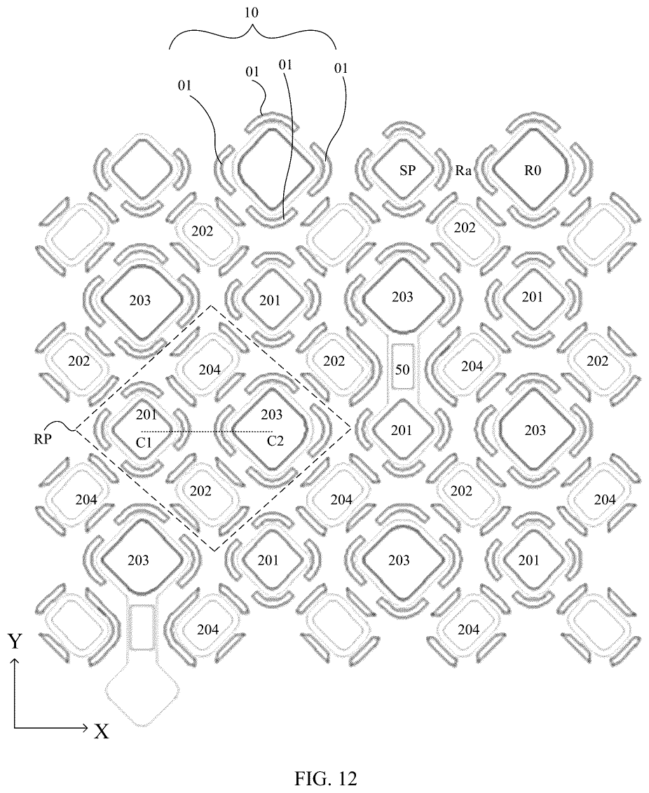

FIG. 12 is a schematic plan view of another display substrate provided by an embodiment of the present disclosure. According to the display substrate provided by the embodiments of the present disclosure, as illustrated in FIG. 12, the separation structure 10 includes at least one separation sub-structure 01, the orthographic projection of the at least one separation sub-structure 01 on the base substrate BS at least surrounds one half of the orthographic projection of the light-emitting region R0 on the base substrate BS.

As illustrated in FIG. 12, the light-emitting region R0 of each sub-pixel SP is surrounded by three or four separation sub-structures 01. The number of separation sub-structures 01 can be set as required.

As illustrated in FIG. 11 and FIG. 12, the display substrate includes a first sub-pixel 201, a second sub-pixel 202, a third sub-pixel 203, and a fourth sub-pixel 204. For example, one of the first sub-pixel 201 and the third sub-pixel 203 is a blue sub-pixel, the other of the first sub-pixel 201 and the third sub-pixel 203 is a red sub-pixel, and the second sub-pixel 202 and the fourth sub-pixel 204 may be sub-pixels of the same color, e.g., both are green sub-pixels. The light-emitting colors of the first sub-pixel 201, the second sub-pixel 202, the third sub-pixel 203, and the fourth sub-pixel 204 can be set as required.

For example, as illustrated in FIG. 11 and FIG. 12, one first sub-pixel 201, one second sub-pixel 202, one third sub-pixel 203, and one fourth sub-pixel 204 constitute a repeating unit RP. In the repeating unit RP, the second sub-pixel 202 and the fourth sub-pixel 204 are disposed on both sides of the connecting line CL connecting the centers of the first sub-pixel 201 and the third sub-pixel 203 respectively. FIG. 11 and FIG. 12 illustrate the center C1 of the first sub-pixel 201 and the center C2 of the third sub-pixel 203. Correspondingly, the first sub-pixel 201 and the third sub-pixel 203 are also disposed on both sides of a connecting line connecting the centers of the second sub-pixel 202 and the fourth sub-pixel 204 respectively.

For example, in other embodiments, only one separation structure is provided between two adjacent sub-pixels, so that the width of the interval between two adjacent sub-pixels can be reduced so as to increase the pixel density.

FIG. 11 and FIG. 12 also illustrate a spacer 50. The spacer 50 is configured to support a fine metal mask when forming a light-emitting layer.

As illustrated, the spacer 50 is in the area surrounded by the first sub-pixel 201, the second sub-pixel 202, the third sub-pixel 203, and the fourth sub-pixel 204.

As illustrated in FIG. 12, a spacer 50 is disposed between the first sub-pixel 201 and the third sub-pixel 203 which are arranged in the second direction Y.

FIG. 11 and FIG. 12 illustrate the direction X and the direction Y. The direction X intersects the direction Y. For example, the direction X is perpendicular to the direction Y. Both the direction X and the direction Y are directions parallel to the main surface of the base substrate. For example, the direction Z is perpendicular to the direction X and perpendicular to the direction Y.

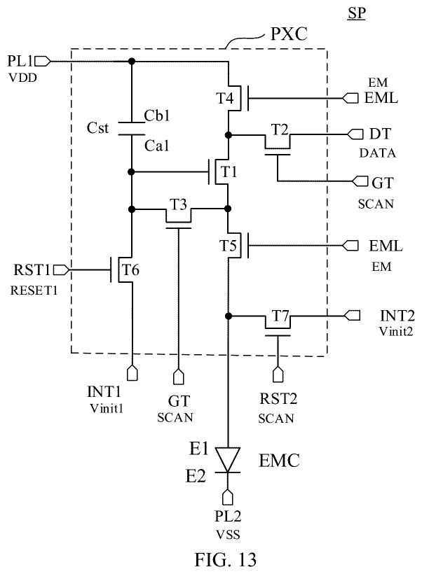

FIG. 13 is a schematic diagram of a pixel circuit and a light-emitting element in a display substrate. FIG. 13 is illustrated by taking the pixel circuit of 7T1C as an example. It should be noted that the pixel circuit is not limited to that illustrated in FIG. 13, and can be set as required. As illustrated in FIG. 13, the display substrate includes a sub-pixel SP, and the sub-pixel includes a pixel circuit PXC and a light-emitting element EMC. The light-emitting element EMC includes a first electrode E1, a second electrode E2, and a light-emitting functional layer located between the first electrode E1 and the second electrode E2. The pixel circuit PXC includes a transistor and a storage capacitor Cst. For example, the transistor includes transistors T1-T7, and the storage capacitor Cst includes an electrode plate Ca1 and an electrode plate Cb1. FIG. 13 also illustrates a gate line GT providing the scan signal SCAN, a data line DT providing the data signal DATA, a light-emitting control signal line EML providing the light-emitting control signal EM, a power line PL1 providing the power supply voltage VDD, a power line PL2 providing the power supply voltage VSS, a reset control signal line RST1 providing the reset signal RESET, a reset control signal line RST2 providing the scan signal SCAN, an initialization signal line INT1 providing the initialization signal Vinit1, and an initialization signal line INT2 providing the initialization signal Vinit2.

For example, as illustrated in FIG. 13, the transistor T1 is a driving transistor, the transistor T2 is a data writing transistor, the transistor T3 is a threshold compensation transistor, the transistor T4 is a light-emitting control transistor, the transistor T5 is a light-emitting control transistor, the transistor T6 is a reset control transistor, and the transistor T7 is a reset control transistor.

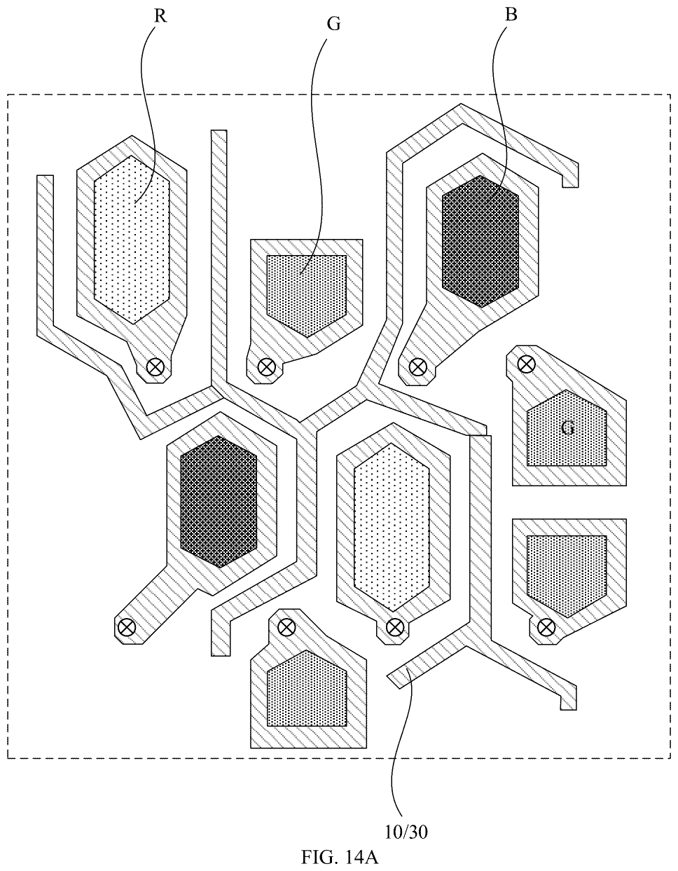

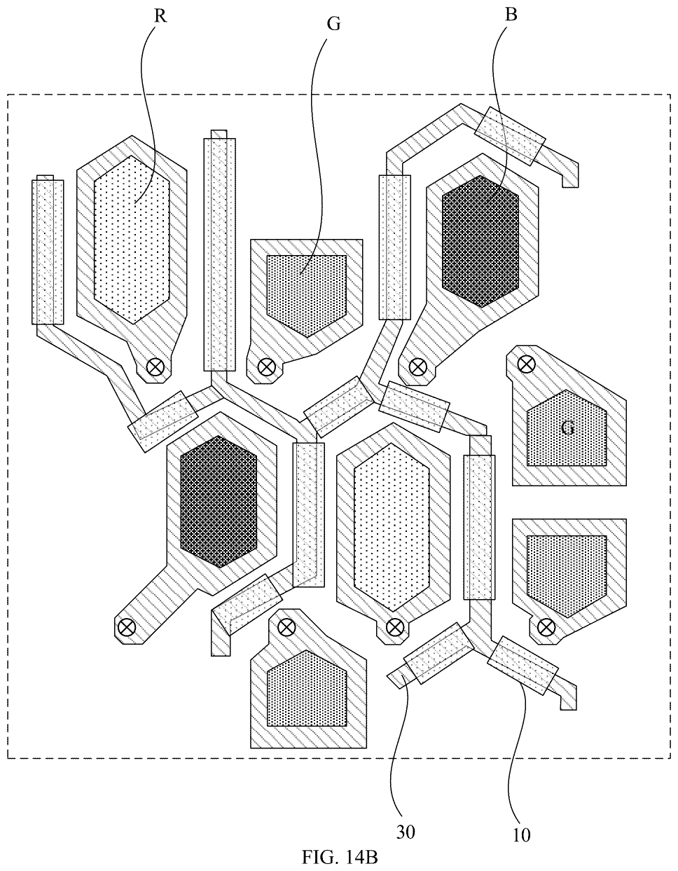

FIG. 14A is a schematic diagram of a display substrate provided by an embodiment of the present disclosure. FIG. 14B is a schematic diagram of a display substrate provided by another embodiment of the present disclosure.

As illustrated in FIG. 14A and FIG. 14B, according to the display substrate provided by the embodiments of the present disclosure, the display substrate further includes a conductive structure 30, the conductive structure 30 is configured to provide signals to the pixel circuit, the conductive structure 30 is located between the separation structure 10 and the base substrate BS, and the orthographic projection of the conductive structure 30 on the base substrate BS overlaps the orthographic projection of the separation structure 10 on the base substrate BS. For example, the conductive structure 30 may be located in the third conductive pattern layer LY3, and the separation structure 10 is formed after the conductive structure 30 is formed. Of course, the conductive structure 30 may also be located in any other layer. For example, for a display substrate with a low PPI, the conductive structure 30 may be in the same layer as the first electrode E1 if there are sufficient wiring positions.

In some embodiments, as illustrated in FIG. 14A, the orthographic projection of the conductive structure 30 on the base substrate BS overlaps the orthographic projection of the separation structure 10 on the base substrate BS.

In some embodiments, as illustrated in FIG. 14B, the orthographic projection of the conductive structure 30 on the base substrate BS partially overlaps the orthographic projection of the separation structure 10 on the base substrate BS.

For example, the connection of the conductive structure 30 to the second electrode E2 can greatly reduce the resistance of the second electrode E2 (VSS) and reduce the voltage drop on the second electrode E2, thereby reducing the voltage difference between the power supply voltage VSS and the power supply voltage VDD in the display substrate and better reducing the power consumption of the display substrate. For example, according to the IR-Drop simulation results, the voltage drop on the second electrode E2 (VSS) can be reduced by about 0.5V.

For example, according to the display substrate provided by the embodiments of the present disclosure, the conductive structure 30 is located between the light-emitting regions R0 of adjacent sub-pixels SP, and the conductive structure 30 is electrically connected to the second electrode E2. The position at which the conductive structure 30 is connected to the second electrode E2 may be located in the peripheral area, but is not limited thereto. For example, the peripheral area can be a frame area of the display substrate. The display area may be an area where a display image of the display substrate is displayed. The display area includes a light-emitting region R0 and an interval region Ra between adjacent sub-pixels. For example, the peripheral area is located on at least one side of the display area. For example, the peripheral area surrounds the display area.

For example, the second electrode E2 is the cathode of the light-emitting element, and the first electrode E1 is the anode of the light-emitting element. In the case that the second electrode E2 is a continuous electrode on the entire surface and is not disconnected by the separation structure 10, the resistance of the second electrode E2 can be reduced and signal transmission on the second electrode E2 is facilitated.

In some embodiments, each sub-functional layer of the light-emitting functional layer FL is disconnected by the separation structure 10 so as to reduce crosstalk between adjacent sub-pixels; and the second electrode E2 is a continuous electrode on the entire surface and is not disconnected by the separation structure 10, thus reducing resistance of the second electrode E2 and facilitating signal transmission on the second electrode E2.

Embodiments of the present disclosure further provide a display device, including any one of the display substrates as described above. For example, the display substrate in the embodiments of the present disclosure may also be referred to as a display panel.

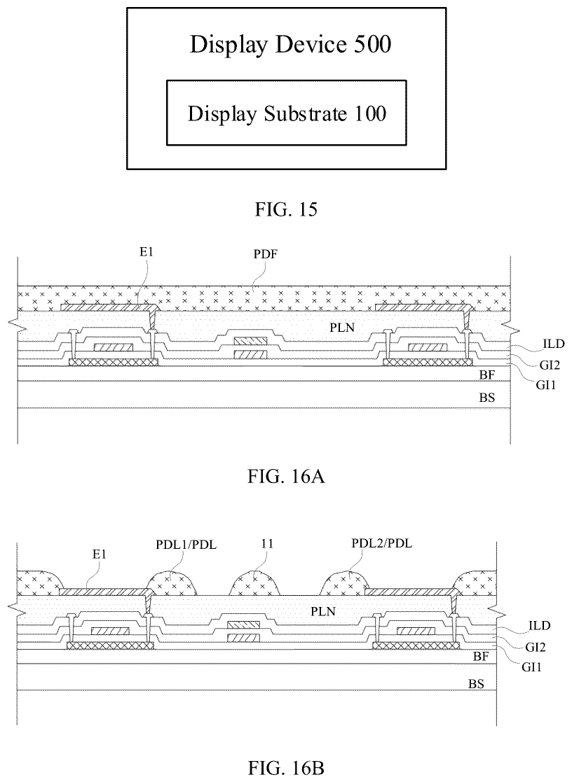

FIG. 15 is a schematic diagram of a display device provided by an embodiment of the present disclosure. As illustrated in FIG. 15, the display device 500 includes a display substrate 100. The display substrate 100 is any one of the display substrates as described above.

On the one hand, the display substrate is provided with a separation structure between adjacent sub-pixels, and at least one sub-functional layer (for example, charge generation layer) in the light-emitting functional layer is disconnected at the position where the separation structure is located, thereby avoiding crosstalk between adjacent sub-pixels caused by the sub-functional layer (for example, charge generation layer) having high conductivity. Therefore, the display device including the display substrate can also avoid crosstalk between adjacent sub-pixels, thus having a high product yield and high display quality.

On the other hand, the display substrate can have a tandem structure so as to increase pixel density. Therefore, the display device including the display substrate has the advantages of a long lifespan, low power consumption, high brightness, high resolution and the like.

For example, the display device can be an organic light-emitting diode display device or the like, and can also be any product or component with a display function such as a TV, a digital camera, a mobile phone, a watch, a tablet, a laptop, a navigator, or the like including the display device. Embodiments of the present disclosure include but are not limited to thereto.

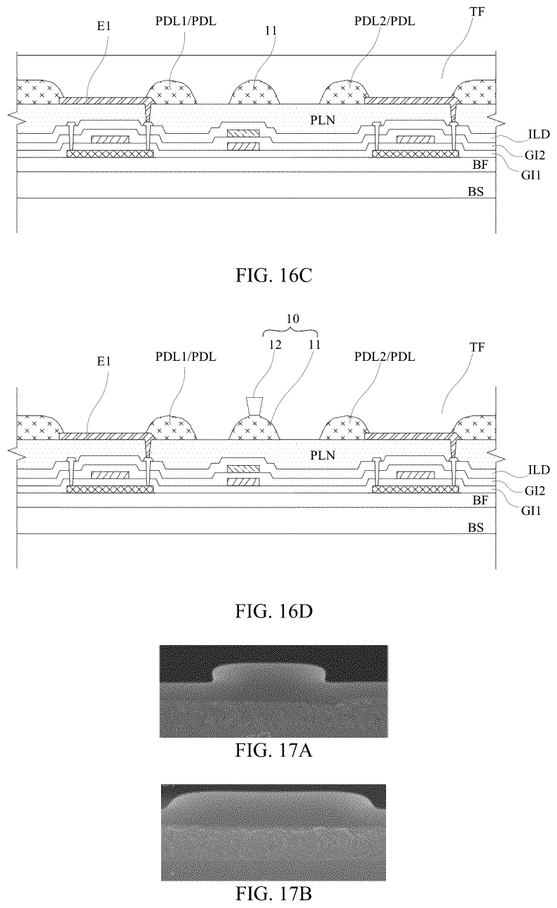

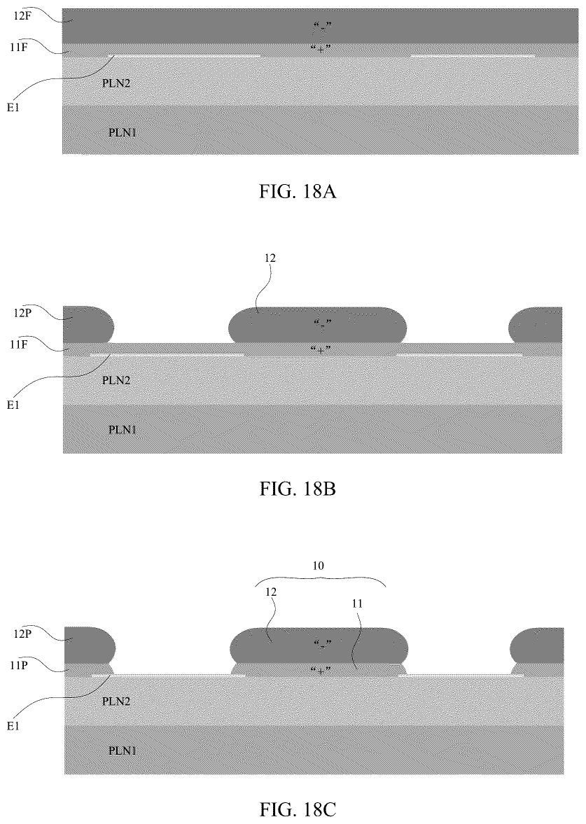

FIG. 16A to FIG. 16D are schematic diagrams of a manufacturing method of a display substrate provided by an embodiment of the present disclosure. FIG. 17A is a schematic cross-sectional view of a negative photoresist after exposure and development. FIG. 17B is a schematic cross-sectional view of the positive photoresist after exposure and development. FIG. 18A to FIG. 18C are schematic diagrams of a manufacturing method of a display substrate provided by an embodiment of the present disclosure.

Referring to FIG. 3, FIG. 5, FIG. 7, FIG. 16A to FIG. 16D, and FIG. 18A to FIG. 18C, embodiments of the present disclosure further provide a manufacturing method of a display substrate, including the following steps:
S11. Forming a plurality of sub-pixels SP on the main surface of the base substrate BS. The sub-pixel SP includes a light-emitting element EMC, the light-emitting element EMC has a light-emitting region R0, the light-emitting element EMC includes a first electrode E1, a light-emitting functional layer FL, and a second electrode E2, the second electrode E2 is located on the side of the light-emitting functional layer FL facing away from the base substrate BS, the first electrode E1 is located on the side of the light-emitting functional layer FL close to the base substrate BS, and the light-emitting functional layer FL includes a plurality of sub-functional layers.
S12. Forming a separation structure 10 between the light-emitting regions R0 of adjacent sub-pixels SP. Forming the separation structure 10 includes forming a first separation part 11 and a second separation part 12 which are stacked, the first separation part 11 is located on the side of the second separation part 12 close to the base substrate BS; the second separation part 12 has a protruding part PR, the protruding part PR protrudes relative to the side of the first separation part 11 close to the second separation part 12, at least one sub-functional layer of the light-emitting functional layer is disconnected at the protruding part PR, the material of the first separation part 11 includes an organic material, the material of the second separation part 12 includes an organic material, and along the direction from the first electrode E1 to the second electrode E2, the orthographic projection of the separation structure 10 on the base substrate BS gradually decreases and then gradually increases.

As illustrated in FIG. 16A to FIG. 16D, the manufacturing method of the display substrate provided by the embodiments of the present disclosure includes the following steps.
S21, as illustrated in FIG. 16A, forming a pixel-defining film PDF on the base substrate BS on which a first electrode E1 is formed.
S22, as illustrated in FIG. 16B, patterning the pixel-defining film PDF to form a pixel-defining pattern and a first separation part 11.
S23, as illustrated in FIG. 16C, forming a support film TF on the pixel-defining pattern and the first separation part 11.
S24, as illustrated in FIG. 16D, patterning the support film TF to form a second separation part 12.

For example, the second separation part 12 may serve as a spacer to support a fine metal mask when forming a light-emitting layer.

In the case that the second separation part 12 is also used as a spacer, in one aspect, the separation structure 10 can be formed by only changing the pixel-defining pattern and the shape of the spacer, without increasing the number of masks, thus facilitating the manufacture of a display substrate. In another aspect, the separation structure 10 is formed after the first electrode E1 is formed, which does not affect the manfacture of the backplane. In a further aspect, the space for manufacturing the separation structure 10 is large, which facilitates the formation of a separation structure 10 with a large size.

As illustrated in FIG. 17A, the structure formed after exposure and development of the negative photoresist is large at the top and small at the bottom. As illustrated in FIG. 17B, the structure formed after exposure and development of the positive photoresist is small at the top and large at the bottom. The properties of the positive photoresist and the negative photoresist can be utilized to form a separation structure so as to disconnect at least one sub-functional layer of the light-emitting functional layer.

As illustrated in FIG. 18A to FIG. 18C, according to the manufacturing method of the display substrate provided by the embodiments of the present disclosure, forming a first separation part 11 and a second separation part 12 which are stacked includes the following steps.
S01, as illustrated in FIG. 18A, forming a positive photoresist film 11F.
S02, as illustrated in FIG. 18A, forming a negative photoresist film 12F on the positive photoresist film 11F.
S03, as illustrated in FIG. 18B, patterning the negative photoresist film 12F to form a second separation part 12.
S04, as illustrated in FIG. 18C, patterning the positive photoresist film by using the second separation part 12 as a mask to form a first separation part 11, thereby forming a separation structure 10.

After step S04, the following steps may also be included.
S05, forming a light-emitting functional layer, at least one functional sublayer of the light-emitting functional layer being disconnected at the protruding part of the separation structure 10.
S06, forming a second electrode E2. The second electrode E2 may or may not be disconnected at the protruding part of the separation structure 10.

FIG. 18B illustrates a pattern 12P of the pixel-defining sublayer, the pattern 12P of the pixel-defining sublayer including the second isolaton part 12.

FIG. 18C illustrates a pattern 11P of the pixel-defining sublayer, the pattern 11P of the pixel-defining sublayer including the first separation part 11.

For example, the thickness of the positive photoresist film 11F may be 0.5 μm-1 μm. For example, the thickness of the first separation part 11 may be 0.5 μm-1 μm.

For example, the thickness of the negative photoresist film 12F may be 1.2 μm-2 μm. For example, the thickness of the second separation part 12 may be 1.2 μm-2 μm.

In step S03, when performing first exposure, a mask plate can be used for masking to expose the negative photoresist, and an inverted trapezoid pattern can be formed in the exposed area.

In step S04, when performing second exposure, the positive photoresist is exposed again using the pattern of the negative photoresist. According to the exposure depth, the positive photoresist under the negative photoresist is not exposed, and the positive photoresist not masked by the negative photoresist will be removed after exposure. Finally, an inverted gourd-like shape is formed, and the resistance of the sub-functional layer such as the charge generation layer (CGL) is increased by the shape, so as to reduce the crosstalk between adjacent sub-pixels upon luminescence.

The display substrate illustrated in FIG. 7 can be formed by using the method illustrated in FIG. 18A to FIG. 18C.

As illustrated in FIG. 7 and FIG. 18C, the pixel-defining pattern PDL and the separation structure 10 are of an integral structure. It can be regarded that the pixel-defining pattern PDL is also used as the separation structure 10.

For the manufacturing method illustrated in FIG. 18A to FIG. 18C and the display substrate illustrated in FIG. 7, at least one of the following effects is provided.
(1) The separation structure 10 can be formed by only changing the shape of the pixel-defining pattern, without increasing the number of masks, thus facilitating the manufacture of the display substrate.
(2) The separation structure 10 is formed after the first electrode E1 is formed, which does not affect the manufacture of the backplane.
(3) The separation structure 10 is also used as a pixel-defining pattern, and is formed at the same time with the opening area of the pixel-defining pattern without the need to manufacture a new separation structure, thus simplifying the manufacturing process.
(4) The separation structure 10 is manufactured by using a mask plate, and the second separation part 12 formed by the negative resist is used as a mask of the positive photoresist, thus avoiding the problem of overlay in the exposure process and making it suitable for the manufacture of a display substrate with very high PPI.

In FIG. 18A to FIG. 18C, “+” indicates a positive photoresist, and “−” indicates a negative photoresist. Photoresist refers to a material whose solubility is changed by irradiation or radiation of ultraviolet light, electron beams, ion beams, X-rays, and the like. For the positive photoresist, the exposed parts are removed after development, and the unexposed parts are kept after development. For the negative photoresist, the exposed parts are kept after development, and the unexposed parts are removed after development.

There are three main differences between the negative photoresist and the positive photoresist.
(1) The exposure and development processes are different. The positive photoresist is developed in the exposure area. On the contrary, the exposure area of the negative photoresist is retained.
(2) The contours formed by diffused light at the boundary of the negative photoresist and the positive photoresist are different. For the positive photoresist, the contour formed by diffused light makes the structure after development wide at the bottom and narrow at the top. On the contrary, for the negative photoresist, the structure is wide at the top and narrow at the bottom.
(3) The positive photoresist is soluble in strong alkali, and an alkaline solution is used as a developer, while an organic solution (such as an xylene solution) is mostly used as a developer for the negative photoresist.

As illustrated in FIG. 18A to FIG. 18C, the positive photoresist and the negative photoresist are exposed using the same mask plate, and according to the exposure principles of the positive photoresist and the negative photoresist as well as the different properties of the developing solution, an inverted “gourd-shaped” columnar separation structure is formed, and the shape is used to increase the resistance of the sub-functional layer (for example, charge generation layer (CGL)) in the light-emitting functional layer and to reduce crosstalk.

For example, in the embodiments of the present disclosure, the components located in the same layer may be formed from the same film layer by the same patterning process. In the embodiments of the present disclosure, the patterning or patterning process may include a photolithography process only, or include a photolithography process and an etching process, or may include printing, inkjetting and other processes for forming a predetermined pattern. The photolithography process includes film formation, exposure, development, etc., and uses a photoresist, a mask plate, an exposure machine, etc. to form a pattern. A corresponding patterning process can be selected according to the structure formed in the embodiments of the present disclosure.

For example, in the embodiments of the present disclosure, the thickness of a component refers to the dimension of the component in a direction perpendicular to the base substrate.

For example, in the embodiments of the present disclosure, the base substrate BS, the buffer layer BF, the gate insulating layer GI1, the gate insulating layer GI2, the interlayer insulating layer ILD, the planarization layer PLN, the planarization layer PLN1, and the planarization layer PLN2 are all made of insulating materials. For example, the material of the base substrate BS includes polyimide, but is not limited thereto. For example, the base substrate BS may be a flexible base substrate so as to form a flexible display substrate. For example, the materials of the buffer layer BF, the gate insulating layer GI1, the gate insulating layer GI2, and the interlayer insulating layer ILD include inorganic insulating materials. For example, the materials of the planarization layer PLN, the planarization layer PLN1 and the planarization layer PLN2 include organic insulating materials. For example, the inorganic insulating material includes at least one of silicon oxide, silicon nitride, and silicon oxynitride. For example, the organic insulating material includes one of acrylic, polyethylene terephthalate, polyimide, polyamide, polycarbonate, epoxy resin, and the like, or a combination thereof.

For example, in the embodiments of the present disclosure, the gate electrode GE, the first electrode plate Ca, the second electrode plate Cb, the source electrode Ea and the drain electrode Eb are made of a metal or alloy.

For example, in the embodiments of the present disclosure, the active layer ACT is a semiconductor layer, and polysilicon or a metal oxide semiconductor can be used.

The above are only specific embodiments of the present disclosure, but the protection scope of the present disclosure is not limited thereto. Any person skilled in the art can easily think of changes or substitutions within the technical scope disclosed in the present disclosure. It should be covered within the protection scope of the present disclosure. Therefore, the protection scope of the present disclosure should be determined by the protection scope of the claims.

1. A display substrate, comprising:
a base substrate;
a plurality of sub-pixels located on a main surface of the base substrate, wherein the sub-pixel comprises a light-emitting element, the light-emitting element has a light-emitting region, the light-emitting element comprises a first electrode, a light-emitting functional layer, and a second electrode, the second electrode is located on a side of the light-emitting functional layer facing away from the base substrate, the first electrode is located on a side of the light-emitting functional layer close to the base substrate, and the light-emitting functional layer comprises a plurality of sub-functional layers; and
a separation structure located between light-emitting regions of adjacent sub-pixels and comprising a first separation part and a second separation part which are stacked, wherein the first separation part is located on a side of the second separation part close to the base substrate,
wherein the second separation part has a protruding part, the protruding part protrudes relative to a side of the first separation part close to the second separation part, at least one sub-functional layer of the light-emitting functional layer is disconnected at the protruding part, a material of the first separation part comprises an organic material, a material of the second separation part comprises an organic material, and along a direction from the first electrode to the second electrode, an orthographic projection of the separation structure on the base substrate gradually decreases and then gradually increases.

2. The display substrate according to claim 1, wherein the second separation part is in contact with the first separation part.

3. The display substrate according to claim 1, wherein the separation structure is in the shape of a gourd or an hourglass.

4. The display substrate according to claim 1, wherein the separation structure comprises a bottom surface, a top surface, and two side surfaces located between the bottom surface and the top surface, the side surfaces are V-shaped, and the bottoms of the two V characters are arranged opposite to each other.

5. The display substrate according to claim 1, wherein on the same side of the separation structure, an included angle between a side surface of the first separation part and a side surface of the second separation part is greater than or equal to 60 degrees and less than or equal to 150 degrees.

6. The display substrate according to claim 1, wherein an included angle between a portion of the second separation part close to the top surface of the separation structure and the top surface is an acute angle, and the acute angle is greater than or equal to 60 degrees and less than or equal to 80 degrees.

7. The display substrate according to claim 1, wherein an included angle between a portion of the second separation part close to a top surface of the separation structure and the top surface is an obtuse angle, and the obtuse angle is greater than 110 degrees and less than or equal to 160 degrees.

8. The display substrate according to claim 1, further comprising:
a pixel-defining pattern, comprising a plurality of openings, each of the plurality of openings being configured to define the light-emitting region of the sub-pixel and configured to expose at least a portion of the first electrode,
wherein the pixel-defining pattern comprises a portion located in the same layer as the first separation part.

9. The display substrate according to claim 8, wherein the pixel-defining pattern is at least partially separated from the first separation part, and both the pixel-defining pattern and the first separation part are in contact with the same insulating layer and located on the insulating layer.

10. The display substrate according to claim 8, wherein the pixel-defining pattern comprises a first pixel-defining part and a second pixel-defining part between two adjacent openings, the separation structure is located between the first pixel-defining part and the second pixel-defining part, a first recess is provided between the separation structure and the first pixel-defining part, and a second recess is provided between the separation structure and the second pixel-defining part.

11. The display substrate according to claim 8, wherein an orthographic projection of the protruding part on the base substrate at least partially overlaps an orthographic projection of the first electrode on the base substrate,
wherein the pixel-defining pattern and the separation structure are of an integral structure.

12. (canceled)

13. The display substrate according to claim 1, wherein a material of the first separation part comprises a positive photoresist, and a material of the second separation structure comprises a negative photoresist.

14. The display substrate claim 1, wherein the light-emitting functional layer comprises a charge generation layer, a first light-emitting layer, and a second light-emitting layer which are stacked, the first light-emitting layer is located between the first electrode and the charge generation layer, the second light-emitting layer is located between the second electrode and the charge generation layer, and the charge generation layer is disconnected at the protruding part,
wherein the light-emitting functional layer further comprises a first charge transport layer located between the first electrode and the first light-emitting layer and a second charge transport layer located between the first light-emitting layer and the charge generation layer, and the first charge transport layer and the second charge transport layer are disconnected at the protruding part.

15-17. (canceled)

18. The display substrate according to claim 1, further comprising a pixel circuit, wherein the pixel circuit is configured to drive the light-emitting element to emit light, the display substrate further comprises a planarization layer, the first electrode is connected to the pixel circuit through a via hole running through the planarization layer, and both the first electrode and the first separation part are located on the planarization layer,
wherein both the first electrode and the first separation part are in contact with the planarization layer.

19. (canceled)

20. The display substrate according to claim 18, wherein the pixel circuit comprises a capacitor, and an orthographic projection of the capacitor on the base substrate at least partially overlaps an orthographic projection of the separation structure on the base substrate.

21. The display substrate according to claim 18, further comprising a conductive structure, wherein the conductive structure is configured to provide a signal to the pixel circuit, the conductive structure is located between the separation structure and the base substrate, and an orthographic projection of the conductive structure on the base substrate overlaps the orthographic projection of the separation structure on the base substrate,
wherein the conductive structure is located between light-emitting regions of adjacent sub-pixels, and the conductive structure is electrically connected to the second electrode.

22. (canceled)

23. The display substrate according to claim 1, wherein the minimum dimension of the separation structure in a plane parallel to the main surface is greater than a spacing between the first electrodes of adjacent sub-pixels,
wherein the maximum dimension of the separation structure in a plane parallel to the main surface is greater than or equal to one fifth of a spacing between the first electrodes of adjacent sub-pixels.

24. (canceled)

25. A display device, comprising the display substrate according to claim 1.

26. A manufacturing method of a display substrate, comprising:
forming a plurality of sub-pixels on a main surface of a base substrate, wherein the sub-pixel comprises a light-emitting element, the light-emitting element has a light-emitting region, the light-emitting element comprses a first electrode, a light-emitting functional layer, and a second electrode, the second electrode is located on a side of the light-emitting functional layer facing away from the base substrate, the first electrode is located on a side of the light-emitting functional layer close to the base substrate, and the light-emitting functional layer comprses a plurality of sub-functional layers; and
forming a separation structure between light-emitting regions of adjacent sub-pixels, wherein forming the separation structure comprises forming a first separation part and a second separation part which are stacked, and the first separation part is located on a side of the second separation part close to the base substrate,
wherein the second separation part has a protruding part, the protruding part protrudes relative to a side of the first separation part close to the second separation part, at least one sub-functional layer of the light-emitting functional layer is disconnected at the protruding part, a material of the first separation part comprises an organic material, a material of the second separation part comprises an organic material, and along a direction from the first electrode to the second electrode, an orthographic projection of the separation structure on the base substrate gradually decreases and then gradually increases.

27. The manufacturing method according to claim 26, wherein forming the first separation part and the second separation part which are stacked comprises:
forming a positive photoresist film;
forming a negative photoresist film on the positive photoresist film;
patterning the negative photoresist film to form the second separation part; and
patterning the positive photoresist film by using the second separation part as a mask to form the first separation part.
